(19) United States
(12) Patent Application Publication
(10) Pub. No.: US 2009/0039897 A1
(43) Pub. Date: Feb. 12, 2009

(54) Systems and Methods for Scan Chain Testing Using Analog Signals

(75) Inventor: David Fong, San Jose, CA (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: VIA TECHNOLOGIES, INC., Taipei (TW)

(21) Appl. No.: 11/837,128

(22) Filed: Aug. 10, 2007

(51) Int. Cl. G01R 31/00

(52) U.S. Cl. 324/537

(57) ABSTRACT

Systems and methods for utilizing analog signals for scan chain testing of a device are disclosed. At least one embodiment includes a method for utilizing an analog signal for scan chain testing of a device comprising: passing digital input signals from a test module into a signal disassembler configured to divide the digital input signals into bits corresponding to each of the digital input signals, passing the bits into a digital-to-analog converter configured to generate an analog input signal, passing the analog input signal to an analog-to-digital converter within the device under test to obtain bits corresponding to each of the digital input signals, passing the bits as inputs to scan chains within the device under test, and utilizing the bits to test the device under test by the scan chains.

### TECHNICAL FIELD

The present disclosure generally relates to testing of integrated circuits. More particularly, the present disclosure relates to scan chain testing through the use of analog signals.

### BACKGROUND

The technique of utilizing scan chains for board level testing has gained popularity over the years because of the high degree of testability this method provides. By providing low level access for integrated circuits, testing can be performed much more efficiently, resulting in tremendous cost-savings. By way of example, one common test performed using scan chains is the monitoring of flip-flops on integrated circuits on a given printed circuit board (PCB). One of the main advantages of utilizing scan chains is the space savings that are realized over traditional “bed of nail fixtures” used in the past where test probes were physically inserted onto various test points on a given PCB. Understandably, the number of test points could be very limited, given the limited amount of space a particular PCB might have. Scan chain testing achieves a number of purposes. First, scan chain testing provides testing for large scale integrated circuits comprised of millions of gates and ensures that signals properly toggle through testing methods such as fault-toggling. This test method ensures that proper manufacturing of integrated circuits is performed with some degree of certainty. Furthermore, scan chain testing provides a means to test interconnects between integrated circuits on a board. Scan chains integrated into a device can capture data from pin or core logic signals. Alternatively, test data may also be input into pins to test a particular logic block. Data that is captured is then serially shifted out and then examined to determine the characteristics and parameters of the logic block tested. Thus, input data comprised of a pre-defined test pattern can be serially shifted into an integrated scan chain cell. Overall, the use of scan chain testing results in shorter test times, higher test coverage and increased diagnostic capability. However, with pad limited, high-capacity semiconductor chips, it is increasingly difficult to implement a large number of scan chains because of the large number of inputs and outputs needed to transport signals into and out of a chip through the conventional use of digital signals.

### SUMMARY

Systems and methods for utilizing analog signals for scan chain testing are disclosed. Briefly described, one embodiment, among others, is directed to a method for utilizing an analog signal for scan chain testing of a device comprising: passing digital input signals from a test module into a signal disassembler configured to divide the digital input signals into bits corresponding to each of the digital input signals, passing the bits into a digital-to-analog converter configured to generate an analog input signal, passing the analog input signal to an analog-to-digital converter within the device under test to obtain bits corresponding to each of the digital input signals, passing the bits as inputs to scan chains within the device under test, and utilizing the bits to test the device under test by the scan chains.

Another embodiment is directed to a method for utilizing analog signals for scan chain testing of a device comprising: passing digital signals from scan chains to a digital-to-analog converter located within the device to generate an analog output signal, forwarding the analog output signal to an analog-to-digital converter located external to the device to derive the original digital signals in parallel, sending the plurality of digital signals in parallel to a signal assembler configured to combine the plurality of digital signals into a bitstream in a serial fashion, and sending the bitstream to a test unit for analysis.

Another embodiment is directed to a method for utilizing analog signals for scan chain testing of a device comprising: generating a digital test pattern to be sent to a device under test, converting the digital test pattern into an analog input signal, forwarding the analog input signal to the device under test, utilizing the analog input signal for scan chain testing of the device under test and generating an analog output signal, forwarding the analog output signal from the device under test, converting the analog output signal into a digital output signal, and evaluating the digital output signal.

Yet another embodiment is directed to a system for utilizing analog signals for scan chain testing of a device under test comprising: a test module configured to generate digital input signals and receive digital output signals, a first digital-to-analog converter configured to convert the digital input signal into an analog input signal, and a first analog-to-digital converter configured to receive the analog input signal and derive individual bits associated with the digital input signals, and scan chains configured to receive the individual bits for testing the device under test, the scan chains further configured to generate the digital output signals.

Other systems, methods, features, and advantages of the present disclosure will be or may become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of a system and method for utilizing analog inputs/outputs as multiple input/output devices for application of multiple scan chains and the underlying methods can be better understood with reference to the following drawings. The components in the drawings are not necessarily to scale, emphasis instead being placed upon clearly illustrating the principles of application of scan chains through analog signals. Moreover, in the drawings, like reference numerals designate corresponding parts throughout the several views.

FIG. 1A depicts a block diagram of an exemplary scan chain configuration.

FIG. 1B depicts a block diagram of an exemplary scan chain configuration with multiple inputs/outputs.

FIG. 2 depicts a top-level functional diagram for one embodiment of a system for processing multiple scan chains through the use of analog signals.

FIG. 3 depicts a top-level functional diagram for an embodiment of a system for deriving an analog input signal from a test input signal bitstream.

FIG. 4 depicts one embodiment for disassembling a test input signal bitstream into individual bits and passing an analog input signal.

FIG. 5A depicts an alternative embodiment of a system for processing multiple scan chains through the use of analog input signals.

FIG. 5B depicts an alternative embodiment of a system for processing multiple scan chains through the use of analog input signals.

FIG. 6 depicts a top-level functional diagram for one embodiment of a system for deriving a digital output signal bitstream configured as an output and forwarding the analog output signal to a test module.

FIG. 7 depicts a top-level flowchart for one embodiment by which an analog input signal is used for applying a plurality of scan boundary inputs to a device under test.

FIG. 8 depicts a top-level flowchart for the process by which an analog output signal is used for sending a plurality of scan boundary outputs to a test module.

FIG. 9A depicts a block diagram illustrating various components of a test unit.

FIG. 9B depicts a block diagram illustrating an exemplary embodiment of a test unit on which some embodiments may be located.

### DETAILED DESCRIPTION

Having summarized various aspects of the present disclosure, reference will now be made in detail to the description of the disclosure as illustrated in the drawings. While the disclosure will be described in connection with these drawings, there is no intent to limit it to the embodiment or embodiments disclosed herein. On the contrary, the intent is to cover all alternatives, modifications and equivalents included within the spirit and scope of the disclosure as defined by the appended claims.

In this instance, an analog-to-digital converter (ADC) generally refers to a device used for converting an analog signal into a digital signal comprised of a set number of bits. The number of bits is determined by the resolution of the device utilized. Likewise, a digital-to-analog converter (DAC) generally refers to a device used for converting a digital signal comprised of a set number of bits into an analog signal. The number of bits is determined by the resolution of the device utilized. This corresponds to the number of possible output levels the DAC is designated to reproduce. Furthermore, the device under test described herein generally refers to any device, including but not limited to, application specific integrated circuits (ASICs), microprocessors, and digital signal processors (DSPs) containing boundary chains for testing purposes. Finally, test units generally refer to any device used to test electronic components such as printed circuit boards, microprocessors, etc.

One aspect of various embodiments is that the amount of hardware required to implement scan chain testing in a given device is drastically reduced while maintaining the same level of test capability. With pad limited, high-capacity semiconductor chips, it is increasingly difficult to implement a large number of scan chains because of the large number of inputs and outputs needed to transport signals into and out of a chip through the conventional use of digital signals. For example, a 20 Mbyte integrated circuit design could require 200 scan chains with each scan chain comprised of 1,000 flip-flops in order to reasonably reduce the test time of the integrated circuit. Such a large number of additional flip-flops needed to implement scan chain testing can be expensive and can drastically increase the footprint of a given integrated circuit. By using analog signals rather than digital signals, some embodiments provide the same level of testing as traditional scan chain testing but with only a small fraction of the number of inputs and outputs required to receive and output the scan signals.

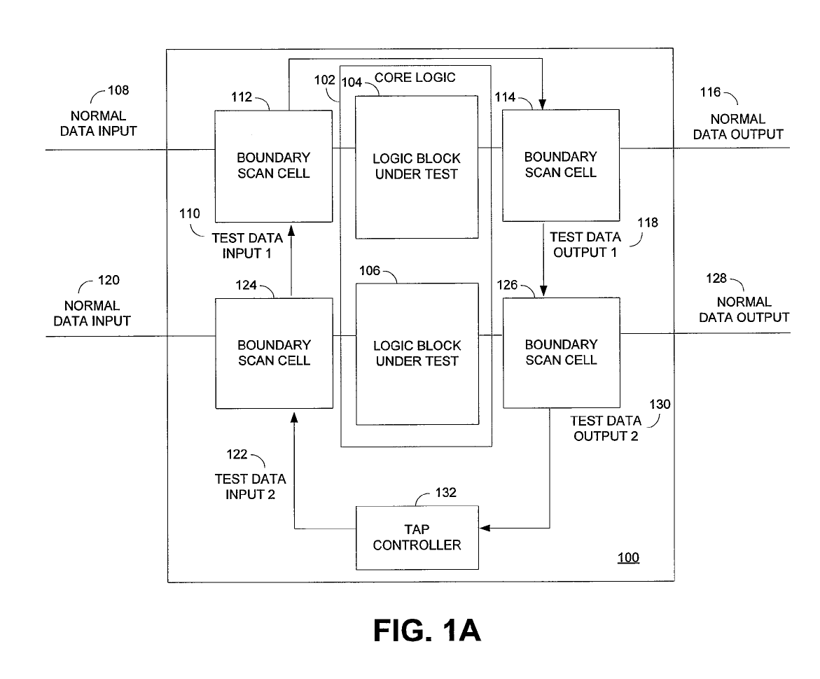

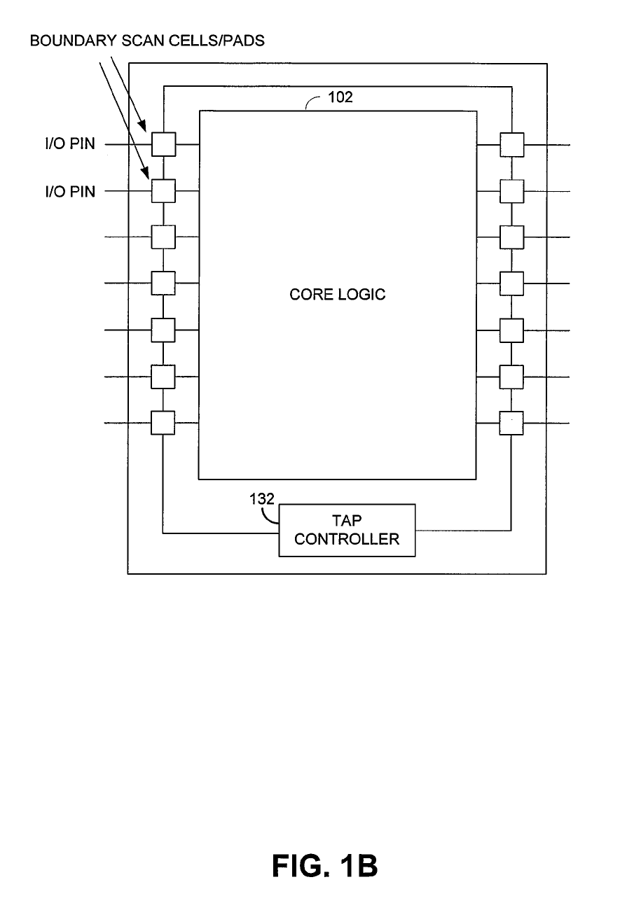

Reference is now made to FIG. 1A, which illustrates an exemplary configuration for boundary scan chain testing. As is generally known, IC level testing within a device may be performed through the use of scan chains integrated into the path of signals flowing in and out of a particular chip. FIG. 1A illustrates an exemplary scan chain configuration for testing some core logic 102. By way of example, the core logic 102 may be comprised of various logic blocks 104, 106. As seen in FIG. 1A, boundary scan cells 112, 114,124, 126 have been integrated into each digital input/output of the logic blocks 104, 106. The boundary scan cells 112, 114, 124, 126 function to provide users with a means to observe normal data flow through the input and output pins. However, the boundary scan cells 112, 114,124, 126 may also inject test signals or test patterns into the logic blocks 104, 106 for testing purposes.

Generally, scan chains operate in a “normal” or “test” mode. When operating in normal mode, the boundary scan cells 112, 114,124, 126 allow normal data flow via the inputs 108, 120 and outputs 116, 128 of the logic blocks 104, 106. The scan chain 100 in these instances is effectively transparent and no signals are modified. The inputs and outputs of the logic block 104, 106 are merely monitored. On the other hand, when operating in test mode, the boundary scan cells 112, 114, 124, 126 allow test data 110, 122 to be driven onto the pins, while the normal data input pins are temporarily isolated from the logic blocks 104, 106. An input signal comprised of a pre-defined test pattern may be driven into the logic blocks 104, 106 via the test data inputs 110, 122 and the response of the logic blocks may be monitored via the test data outputs 118, 130. The TAP (Test Access Port) Controller 132 shown in FIG. 1A controls the boundary scan cells 112, 114, 124, 126 and provides serial scanning of data through the core logic 102 being tested. The TAP controller 132 is common to all JTAG/IEEE-1140.1 compliant devices.

FIG. 1B shows core logic 102 with many boundary scan cells connected together to form a scan chain. As appreciated by those skilled in the art, as the core logic 102 for a given design becomes more and more complex, the amount of space on a printed circuit board can quickly become limited and it may become difficult to insert a large number of boundary scan cells or pads on each input/output pin because of the density of the printed circuit board.

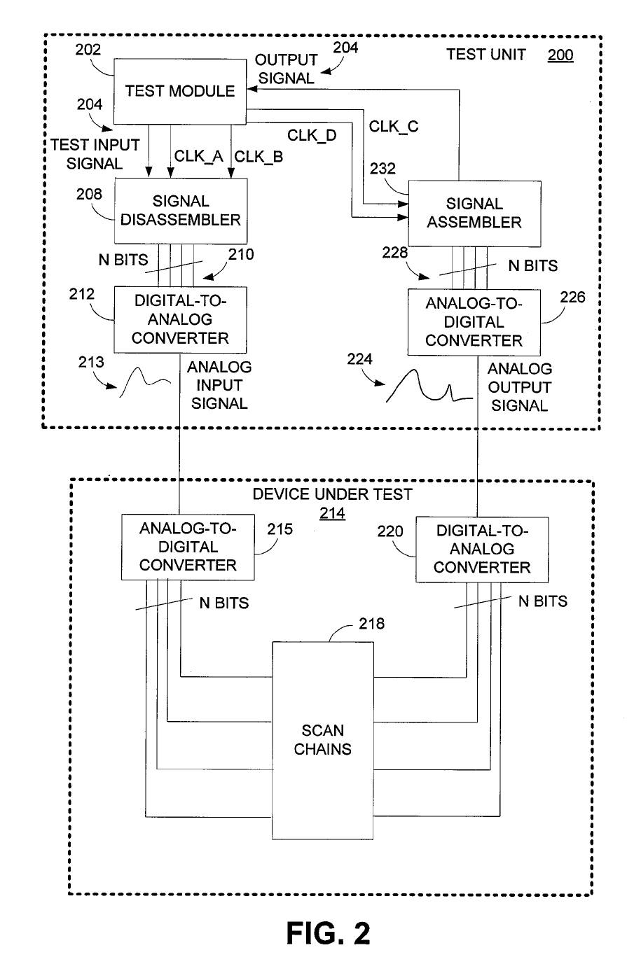

Reference is now made to FIG. 2, which depicts a top-level functional diagram of one embodiment of a system for processing multiple scan chains through the use of analog signals. Shown in FIG. 2 is a test unit 200. The test unit 200 may generally be any device used to test other electronic devices (e.g., integrated circuits, ASICs, DSPs). More specifically, the test unit 200 may be any type of Automatic Test Equipment (ATE), which generally refers to any automated device used to test electronic devices or modules. The test unit 200 may be may be any of a wide variety of computer systems or workstations such as personal computers. However, the test unit 200 may also be a simple controller or measuring device, such as a digital multi-meter.

For some embodiments, the test unit 200 may be comprised of the following modules: a test module 202, a signal disassembler 208, a digital-to-analog converter 212, an analog-to-digital converter 226 and a signal assembler 232. The test unit 200 may be connected to a device under test 214. From a top-level view, the test unit 200 provides test input signals 204 to the device under test 214 and also measures/monitors the response of the device under test 214. Based on the response of the device under test 214, the parameters and characteristics of the device under test 214 may be determined. One aspect of some embodiments is that a plurality of digital inputs may be applied to the device under test 214 via a single analog input, thereby resulting in cost-savings due to a reduced number of inputs on the device under test 214. This can ultimately lead to a smaller footprint for the device under test 214. Likewise, a plurality of digital outputs may be read from the device under test 214 through the use of a single analog output, again thereby resulting in cost-savings due to the reduced number of outputs needed on the under test device 214. The test module 202 within the test unit 200 may be coupled to a signal disassembler 208. The test module 202 generates and sends a test input signal 204 to the device under test 214. The test module 202 also provides clock signals CLK_A, CLK_B to the signal disassembler 208.

Using clock signals CLK_A, CLK_B, the signal disassembler 208 extracts the individual bits 210 which comprise the test input signal 204. Because of the inherent delay involved in extracting the individual bits 210 from the test input signal 204 for some embodiments, the signal disassembler 208 also contains a delay buffer which temporarily stores bits until all the bits 210 have been extracted. The signal disassembler 208 then forwards the bits 210 to the digital-to-analog converter 212. One should note that the number of scan chains 218 located within the device under test 214 is directly proportional to the number of bits in the test input signal 204. By way of illustration, suppose the device under test 214 contains N scan chains 218. The test input signal 204 would be comprised of a bitstream containing some multiple of N bits. For example, suppose there are 125 scan chains 218 located within the device under test 214. In this case, the test input signal 204 would contain some multiple of 125 bits (e.g., 125 bits, 250 bits, 500 bits).

The digital-to-analog converter (DAC) 212 converts the bits 210 forwarded from the signal disassembler 208 into an analog input signal 213. In some embodiments, the DAC 212 will be an N-bit DAC where N is equal to the number of scan chains 218 located within the device under test 214. Thus an N-bit DAC 212 can produce 2^{N} levels of output. The DAC 212 then forwards the analog input signal 213 to the device under test 214. One aspect of some embodiments is the fact that a single analog input signal is utilized to send multiple scan chain inputs. Hence, instead of having a large number of digital inputs, the device under test 214 only needs a single input for the analog input signal.

Within the device under test 214, the analog input signal 213 is forwarded to an analog-to-digital converter 215 where the analog input signal 213 is converted back into a digital signal containing N bits. These N bits are then forwarded to the scan chain 218 for testing purposes.

Once the test input signals have been processed by the device under test 214, the output signals are sent from the scan chain 218 to a digital-to-analog converter 220 where the individual bits are converted into a single analog output signal 224. Another aspect of some embodiments is that a single analog output signal 224 is passed from the device under test 214 to the test module 202.

The analog-to-digital converter 226 forwards the N bits 228 to the signal assembler 232, which is coupled to the test module 202. The signal assembler 232 receives clock signals CLK_C, CLK_D, which the signal assembler 232 uses to construct a bit string of N bits 228 at a time. This string of bits 228 comprises the test output signal 204, which the test module 202 reads and processes.

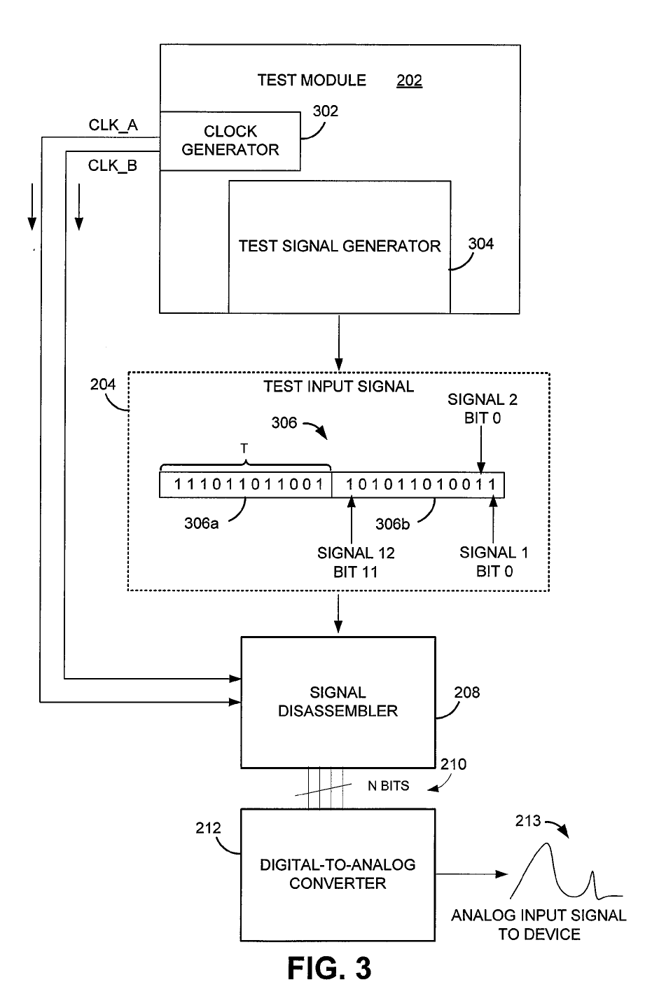

Reference is now made to FIG. 3, which depicts a top-level functional diagram for an embodiment of a system for deriving an analog input signal from a test input signal. The test module 202 is comprised of a clock generator 302, which provides clock signals CLK_A, CLK_B to the signal disassembler 208. For some embodiments, clock signal CLK_A is used by a shift register within the signal disassember 208. The test module 202 also contains a test signal generator 304, which generates a test input signal 204 to be sent to the scan chains 218 within the device under test 214. The test input signal 204 is comprised of multiples of N bits 306, wherein N is equal to the total number of inputs and outputs associated with the scan chains 218 within the device under test 214. As illustrated in FIG. 3, a given test pattern may be comprised of a multiple of N bits 306. Each of the N bits 306 is defined to take a time T to complete transition from the test signal generator 304. In the example shown in FIG. 2, the bitstream is comprised of a multiple of N=12 bits. This corresponds to N=12 inputs.

The test input signal bitstream 204 is then forwarded to the signal disassembler 208, where the individual bits 210 that comprise the test input signal 204 are extracted. The signal disassember 208 performs a serial-to-parallel conversion of the test input signal 204. Bit 0 of the bitstream corresponds to test input signal 1, bit 1 corresponds to test input signal 2, and so on where bit 11 corresponds to test input signal 12. Once the individual bits 210 are extracted, the N=12 bits are then forwarded in parallel to the digital-to-analog converter 212 where a single analog input signal 213 is derived.

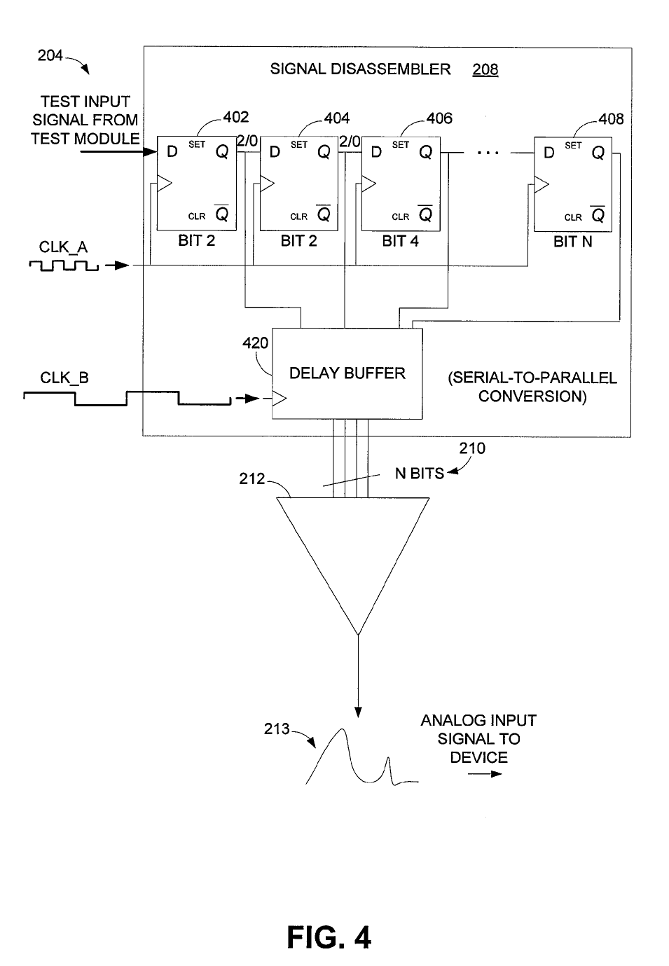

FIG. 4 depicts one embodiment for disassembling a test input signal bitstream into individual bits. For some embodiments, the signal disassembler 208 may include a series of flip-flops 402, 404, 406, 408 cascaded in series to form a shift register. As known by those skilled in the art, a shift register serially shifts a data string in. The data string is then shifted right one stage at a time on each rising clock cycle. FIG. 4 shows one embodiment where a series of D-type flip-flops 402, 404, 406, 408 is cascaded in series and the output (‘Q’ output) of each preceding stage is tied to the input (‘D’ input) of the next stage to make an N-bit shift register. The data is stored after each flip-flop on the ‘Q’ output. Therefore, in FIG. 4, there are N storage locations available. With the cascading D-type flip-flops shown, the test input signal 204 is shifted in serially using clock signal CLK_A and then extracted in a parallel fashion from each of the ‘Q’ outputs. The various ‘Q’ outputs are then fed to a delay buffer 420. Because the N-bit shift register requires N clock pulses to shift all N bits out to the ‘Q’ outputs, there is a delay before all the bits are available for extraction. The delay buffer 420 temporarily stores the data bits until all N bits 210 are available and then shifts N bits 210 in parallel to the digital-to-analog converter 212 using clock signal CLK_B. One should note that the period of CLK_B is N times the period of CLK_A. This ensures that all N bits 210 have been extracted from the shift register before the N bits 210 are forwarded to the digital-to-analog converter 212. Once the N-bits 210 are fed to the digital-to-analog converter 212, an analog input signal 213 is derived.

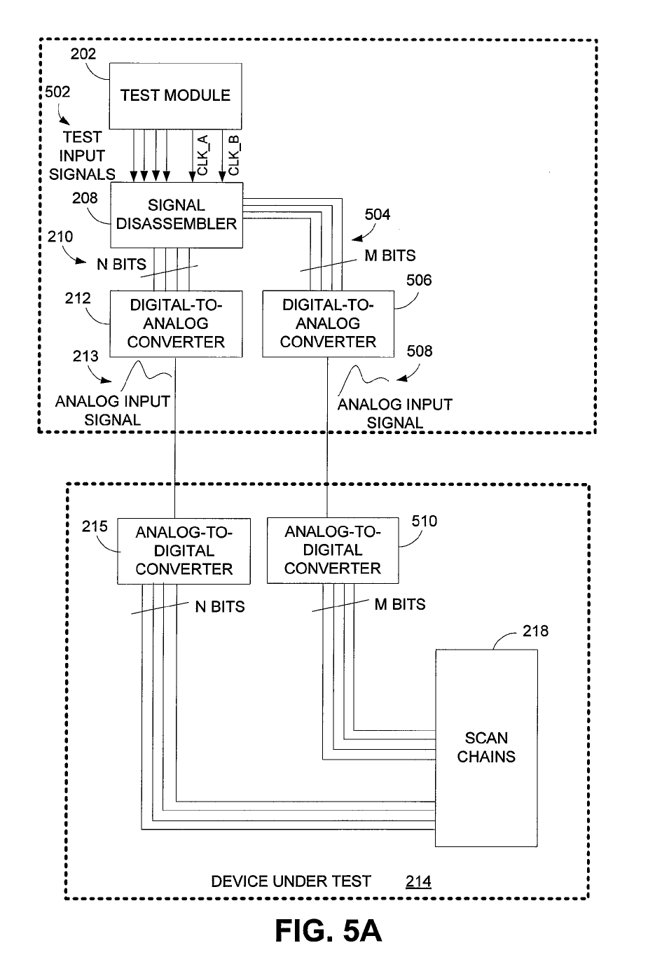

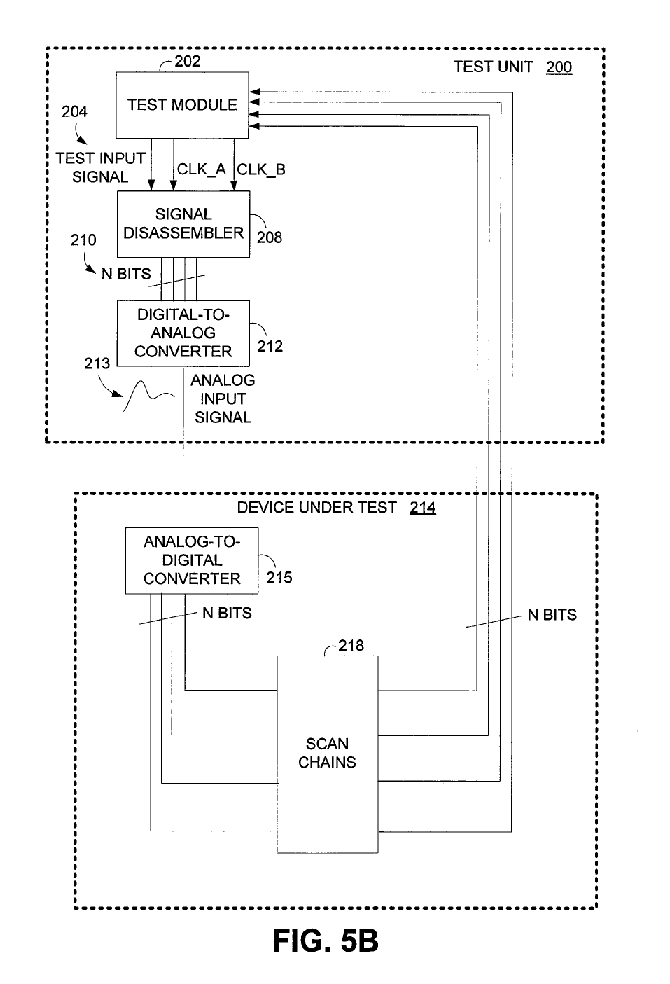

FIG. 5A depicts an alternative embodiment of a system for processing multiple scan chains through the use of analog input signals. In some embodiments, multiple streams of digital data may be converted into multiple analog input signals. For purposes of brevity, only the application of signals to multiple scan chains is discussed. Similar to the embodiment in FIG. 2, the test unit 200 provides test input signals 502 to the device under test 214 and also measures/monitors the response of the device 214 under test. Based on the response of the device under test 214, the parameters and characteristics of the device under test 214 may be determined. One aspect of this embodiment is that a plurality of digital inputs may be applied to the device under test 214 via multiple analog inputs, thereby resulting in cost-savings due to a reduced number of inputs on the device under test 214. Likewise, a plurality of digital outputs may be read from the device under test 214 through the use of multiple analog outputs, again thereby resulting in cost-savings due to the reduced number of outputs needed on the device under test 214. The test module 202 within the test unit 200 may be coupled to a signal disassembler 208. The test module 202 generates and sends a multiple test input signals 502 to the device under test 214. The test module 202 provides a clock signals CLK_A, CLK_B to the signal disassembler 208.

Using clock signals CLK_A, CLK_B, the signal disassembler 208 extracts the individual bits which comprise the test input signal 502. Because of the inherent delay involved in extracting the individual bits 210, 504 from the test input signal 502 for some embodiments, the signal disassembler 208 also contains includes a delay buffer 310 which temporarily stores bits until all the bits 210, 504 have been extracted. The signal disassembler 208 then forwards the bits 210, 504 to the digital-to-analog converters 212, 506. For this embodiment, the signal disassembler 208 takes multiple test input signals 502 from the test module 202 and partitions the bits into N bits 210 and M bits 504. These bits 210, 504 are then fed to digital-to-analog converters (DAC) 212, 506.

The first DAC 212 converts N bits 210 forwarded from the signal disassembler 208 into an analog input signal 213. A second DAC 506 converts M bits 504 coming from the signal disassembler 208 into another analog input signal 508. In some embodiments, the first DAC 212 will be an N-bit DAC, and the second DAC 506 will be an M-bit DAC. The sum (N+M) equals the number of scan chains 218 located within the device under test 214.

The first DAC 212 and second DAC 506 then forward the analog input signals 213, 508 to the device under test 214. Within the device under test 214, the analog input signals 213, 508 are forwarded to analog-to-digital converters 215, 510 where the analog input signals 213, 508 are converted back into digital signals containing N and M bits, respectively. These N+M bits are then forwarded to the scan chains 218 for testing purposes.

FIG. 5B depicts yet another embodiment of a system for processing multiple scan chains through the use of analog signals. As seen in FIG. 5B, one should note that some embodiments may utilize an analog input signal 213 only for inputting a test input signal 204. Digital output signals are then read directly from the device under test 214 by the test unit 200. Other embodiments may utilize an analog output signal only for reading an output signal from the device under test 214. In those cases, digital signals are sent directly to the scan chains 218.

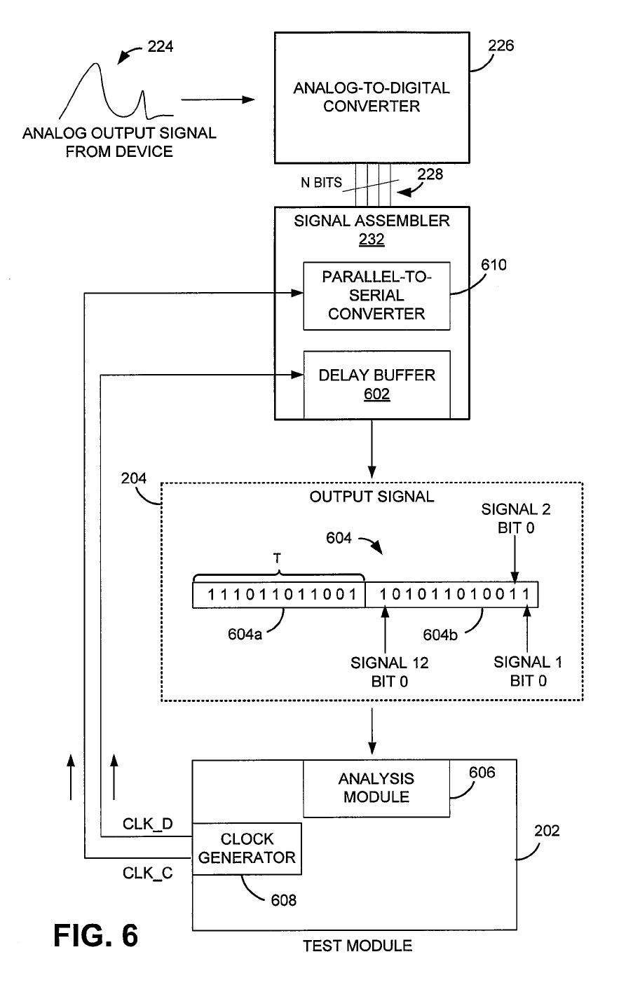

FIG. 6 depicts a top-level functional diagram for one embodiment of a system for deriving a digital signal bitstream configured as an output and forwarding the signal to a test module. An analog output signal 224 is shown, which is located at the output of the device under test 214. Briefly referring back to FIG. 2, the analog output signal 224 is generated by a digital-to-analog converter 220 located within the device under test 214. The analog output signal 224 then passes to an analog-to-digital converter 226 located within the test unit 200, where the analog output signal 224 is converted into N bits 228. The N bits 228 are then fed to the signal assembler 232 where a serial bitstream is constructed. Essentially, one function of the signal assembler 232 is to perform a parallel-to-serial conversion of the digital signal. Clock signal CLK_C is generated by the test module 202 via a clock generator 608 and forwarded to the signal assembler 232 to clock the bits 228 out of the ADC 226 via the parallel-to-serial converter 610. As illustrated in FIG. 6, the signal assembler 232 composes a string of bits. The total number of bits is a multiple of N. For this example, N is equal to 12. Hence, each bitstream is comprised of at least N=12 bits. The signal assembler 232 includes a delay buffer 602 which functions much like the delay buffer 420 discussed in FIG. 4. Using CLK_D, the delay buffer 602 forwards the bitstream comprised of N bits to the analysis module 606. The purpose of the delay buffer 602 is to temporarily store the data due to the finite amount of time needed to clock the N bits through the parallel-to-serial converter 610. Again, one should note that the period of CLK_D is N times the period of CLK_C. Delay buffer 602 forwards a string of N bits 204 once every N cycles of CLK_C since this is the amount of time needed to shift N bits through the parallel-to-serial converter 610.

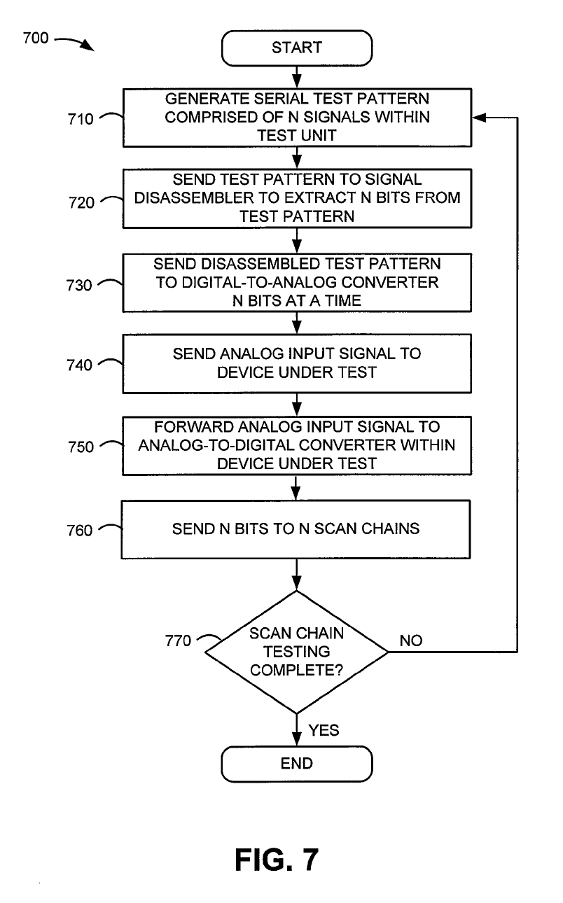

FIG. 7 shows a top-level flowchart for the process for one embodiment by which an analog input signal is used to apply a plurality of scan chain inputs to a device under test. Starting in step 710, a test pattern is first generated. This is the test input signal 204 which later serves as the input for the multiple scan chains 218 located within the device under test 214. The test input signal 204 is comprised of N signals, which correspond to N inputs to be inserted into the scan chains 218. Next in step 720, the test input signal 204 is sent to the signal disassembler 208 where bits are extracted from the test input signal N bits at a time. Once the individual bits are derived from the test input signal 204, the bits are sent to the digital-to-analog converter 212 in a parallel fashion where an analog input signal 213 is generated. In some embodiments, steps 710-730 are performed within the test unit 200. Once the analog input signal 213 is generated, the analog input signal 213 is forwarded to the device under test 214 (step 740) where a digital-to-analog converter 215 located within the device under test 214 converts the analog input signal 213 back into a series of N bits (step 770). The N bits are then routed to the various inputs in the scan chain 218 within the device under test 214 (step 760). Steps 710-760 are repeated until the scan chain testing is completed (step 770).

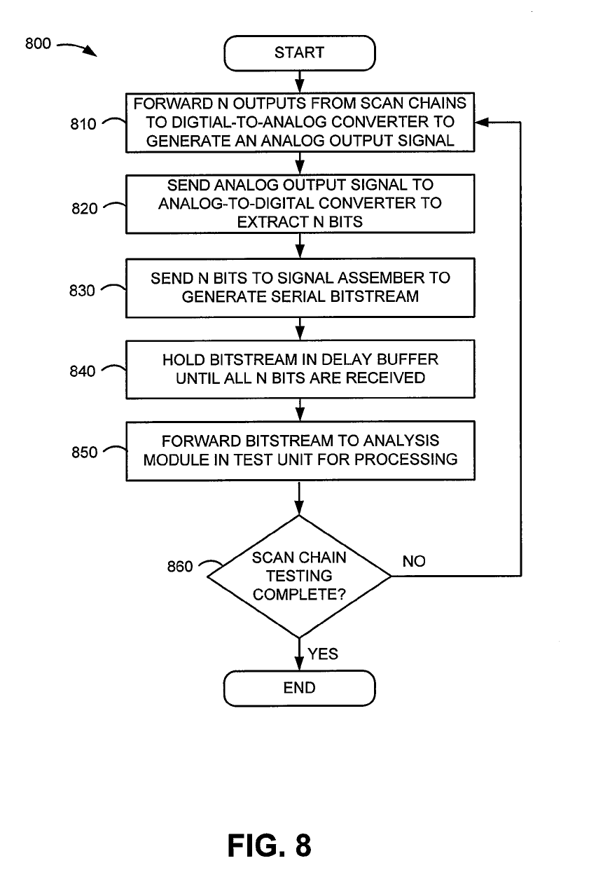

FIG. 8 shows a top-level flowchart for the process for one embodiment by which an analog output signal is used to send outputs from a plurality of scan chains 218 to a test unit 2004. Starting at step 810, the outputs are read from the scan chains 218 and then passed to a digital-to-analog converter 220. Once an analog output signal 224 is generated by the internal DAC 220 of the device under test 214, the analog output signal 224 is forwarded to an analog-to-digital converter 226 located externally from the device under test 214 (step 820). The external ADC 226 converts the analog output signal 224 into a series of bits 228 (step 830), which are then forwarded to the signal assember 232, where the data stream is re-derived. Finally, in step 850, the bits are serially clocked into the test module 202 where the test output signals from the scan chains 218 within the device under test 214 are captured and analyzed. Steps 810-850 are repeated until the scan chain testing is completed (step 860).

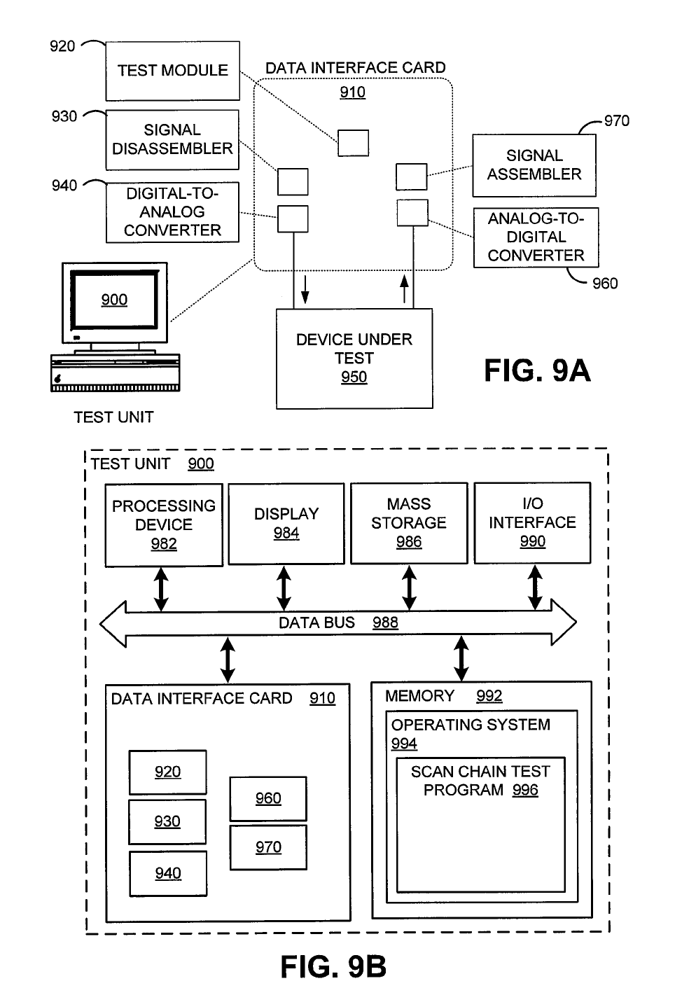

Reference is now made to FIG. 9A, which depicts a block diagram illustrating various components of the test unit 900. In some embodiments, the test unit 900 may include various modules. These modules may be built into the test unit 900 or may reside on a separate but electrically coupled card, such as a general data interface card 910 used for generating and capturing data. The modules on the data interface card 910 may include a test module 920 for generating and analyzing test data, a signal disassembler 930 for providing a serial-to-parallel interface between the test module 920 and the digital-to-analog converter 940, an analog-to-digital converter 960 for receiving an analog output signal from the device under test 950, and a signal assembler 970 for providing a parallel-to-serial interface between the analog-to-digital converter 960 and the test module 920.

FIG. 9B depicts a block diagram illustrating an exemplary embodiment of a test unit on which some embodiments may be located. Generally speaking, the test unit 900 can comprise any one of a wide variety of wired and/or wireless computing devices, such as a desktop computer, portable computer, dedicated server computer, multiprocessor computing device, cellular telephone, personal digital assistant (PDA), handheld or pen based computer, embedded appliance and so forth. Irrespective of its specific arrangement, the test unit 900 can, for instance, comprise memory 992, a processing device 982, a number of input/output interfaces 990, and mass storage 986, wherein each of these devices are connected across a data bus 988. The display 984 for the test unit 900 can comprise a computer monitor or a plasma screen for a PC or a liquid crystal display (LCD) on a hand held device, for example.

Processing device 982 can include a custom made or commercially available processor, a central processing unit (CPU) or an auxiliary processor, a semiconductor based microprocessor (in the form of a microchip), a macroprocessor, one or more application specific integrated circuits (ASICs), a plurality of suitably configured digital logic gates, and other well known electrical configurations comprising discrete elements both individually and in various combinations to coordinate the overall operation of the computing system.

Input/output interfaces 990 provide any of a number of interfaces for the input and output of data. For example, where the test unit 900 comprises a personal computer, these components may interface with a user input device such as a keyboard or a mouse. Where the test unit 900 comprises a handheld device (e.g., PDA, mobile telephone), these components may interface with function keys or buttons, a touch sensitive screen, a stylist, etc.

The memory 992 can include any one of a combination of volatile memory elements (e.g., random-access memory (RAM, such as DRAM, and SRAM, etc.)) and nonvolatile memory elements (e.g., ROM, hard drive, tape, CDROM, etc.). The memory 992 typically comprises a native operating system 994, one or more native applications, emulation systems, or emulated applications for any of a variety of operating systems and/or emulated hardware platforms, emulated operating systems, etc. For some embodiments, the applications may include some type of scan chain test program 996 which allows a user to define test input signals and allows a user to monitor the outputs coming from the device under test. The scan chain test program 996 may interface with the data interface 910 over the data bus 988 to perform scan chain testing of an external device. One of ordinary skill in the art will appreciate that memory 962 can, and typically will, comprise other components which have been omitted for purposes of brevity.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

For example, it will be appreciated by persons skilled in the art, based on the description provided herein that embodiments include a method for utilizing an analog signal for scan chain testing of a device comprising:

passing digital input signals from a test module into a signal disassembler configured to divide the digital input signals into bits corresponding to each of the digital input signals, passing the bits into a digital-to-analog converter configured to generate an analog input signal, passing the analog input signal to an analog-to-digital converter within the device under test to obtain bits corresponding to each of the digital input signals, passing the bits as inputs to scan chains within the device under test, and utilizing the bits to test the device under test by the scan chains.

In certain embodiments, the analog-to-digital converter is an N-bit analog-to-digital converter, wherein N is the number of scan chain inputs. For some embodiments, step of dividing the digital input signal into individual bits is performed using a shift register. In other embodiments, the shift register is comprised of cascading D-type flip-flops, and the individual bits are divided in a serial to parallel fashion.

Another embodiment is directed to a method for utilizing analog signals for scan chain testing of a device comprising: passing digital signals from scan chains to a digital-to-analog converter located within the device to generate an analog output signal, forwarding the analog output signal to an analog-to-digital converter located external to the device to derive the original digital signals in parallel, sending the plurality of digital signals in parallel to a signal assembler configured to combine the plurality of digital signals into a bitstream in a serial fashion, and sending the bitstream to a test unit for analysis.

In certain embodiments, the analog-to-digital converter is an N-bit analog-to-digital converter, wherein N is the number of scan chain outputs. For some embodiments, the test unit is configured to evaluate the bitstream for testing the device. In other embodiments, the test unit contains a delay chain configured to wait until a signal comprised of N bits is received before processing the signal, wherein N is the number of scan chain outputs.

Another embodiment is directed to a method for utilizing analog signals for scan chain testing of a device comprising: generating a digital test pattern to be sent to a device under test, converting the digital test pattern into an analog input signal, forwarding the analog input signal to the device under test, utilizing the analog input signal for scan chain testing of the device under test and generating an analog output signal, forwarding the analog output signal from the device under test, converting the analog output signal into a digital output signal, and evaluating the digital output signal.

In certain embodiments, the conversion of the digital test pattern into the analog input signal is performed with a signal disassembler and an N-bit digital-to-analog converter. For some embodiments, the conversion of the analog output signal from the device under test into the digital output signal is performed with an N-bit analog-to-digital converter and a signal assembler.

Yet another embodiment is directed to a system for utilizing analog signals for scan chain testing of a device under test comprising: a test module configured to generate digital input signals and receive digital output signals, a first digital-to-analog converter configured to convert the digital input signal into an analog input signal, and a first analog-to-digital converter configured to receive the analog input signal and derive individual bits associated with the digital input signals, and scan chains configured to receive the individual bits for testing the device under test, the scan chains further configured to generate the digital output signals.

In certain embodiments, the first digital-to-analog converter is an N-bit digital-to-analog converter. In some embodiments, the first analog-to-digital converter is an N-bit analog-to-digital converter. In some embodiments, the system further comprises a signal disassembler configured to divide the digital input signal from the test module into individual bits and send the individual bits to the first digital-to-analog converter in a serial to parallel fashion. For some embodiments, the signal disassembler is comprised of a shift register configured to output the individual bits of the digital input signals in serial and a delay buffer configured to store the individual bits temporarily. For some embodiments, the value N corresponds to the number of scan chain inputs. In other embodiments, the value N corresponds to the number of scan chain outputs. In some embodiments, the system further comprises a second digital-to-analog converter configured to convert the digital output signal from the scan chains into an analog output signal, a second analog-to-digital converter configured to receive the analog output signal and derive output bits associated with the digital output signal, and a signal assembler configured to construct the output bits from the second analog-to-digital converter into a bit string and send to the test module in a parallel to serial fashion. In other embodiments, the signal assembler further comprises a second delay buffer configured to temporarily store the bit string.

At least the following is claimed:

1. A method for utilizing analog signals for scan chain testing of a device under test comprising:
passing digital input signals from a test module into a signal disassembler configured to divide the digital input signals into bits corresponding to each of the digital input signals;
passing the bits into a digital-to-analog converter configured to generate an analog input signal;
passing the analog input signal to an analog-to-digital converter within the device under test to obtain bits corresponding to each of the digital input signals;
passing the bits as inputs to scan chains within the device under test; and
utilizing the bits to test the device under test by the scan chains.

2. The method of claim 1, wherein the analog-to-digital converter is an N-bit analog-to-digital converter, wherein N is the number of scan chain inputs.

3. The method of claim 1, wherein the step of dividing the digital input signal into individual bits is performed using a shift register.

4. The method of claim 3, wherein the shift register is comprised of cascading D-type flip-flops, and the individual bits are divided in a serial to parallel fashion.

5. A method for utilizing analog signals for scan chain testing of a device comprising:
passing digital signals from scan chains to a digital-to-analog converter located within the device to generate an analog output signal;
forwarding the analog output signal to an analog-to-digital converter located external to the device to derive the original digital signals in parallel;
sending the plurality of digital signals in parallel to a signal assembler configured to combine the plurality of digital signals into a bitstream in a serial fashion; and
sending the bitstream to a test unit for analysis.

6. The method of claim 5, wherein the analog-to-digital converter is an N-bit analog-to-digital converter, wherein N is the number of scan chain outputs.

7. The method of claim 5, wherein the test unit is configured to evaluate the bitstream for testing the device.

8. The method of claim 7, wherein the test unit contains a delay chain configured to wait until a signal comprised of N bits is received before processing the signal, wherein N is the number of scan chain outputs.

9. A method for utilizing analog signals for scan chain testing of a device comprising:
generating a digital test pattern to be sent to a device under test;
converting the digital test pattern into an analog input signal;
forwarding the analog input signal to the device under test;
utilizing the analog input signal for scan chain testing of the device under test and generating an analog output signal;
forwarding the analog output signal from the device under test;
converting the analog output signal into a digital output signal; and
evaluating the digital output signal.

10. The method of claim 9, wherein the conversion of the digital test pattern into the analog input signal is performed with a signal disassembler and an N-bit digital-to-analog converter.

11. The method of claim 9, wherein the conversion of the analog output signal from the device under test into the digital output signal is performed with an N-bit analog-to-digital converter and a signal assembler.

12. A system for utilizing analog signals for scan chain testing of a device under test comprising:
a test module configured to generate digital input signals and receive digital output signals;
a first digital-to-analog converter configured to convert the digital input signal into an analog input signal; and
a first analog-to-digital converter configured to receive the analog input signal and derive individual bits associated with the digital input signals; and
scan chains configured to receive the individual bits for testing the device under test, the scan chains further configured to generate the digital output signals.

13. The system of claim 12, wherein the first digital-to-analog converter is an N-bit digital-to-analog converter.

14. The system of claim 12, wherein the first analog-to-digital converter is an N-bit analog-to-digital converter.

15. The system of claim 12, further comprising a signal disassembler configured to divide the digital input signal from the test module into individual bits and send the individual bits to the first digital-to-analog converter in a serial to parallel fashion.

16. The system of claim 15, wherein the signal disassembler is comprised of a shift register configured to output the individual bits of the digital input signals in serial and a delay buffer configured to store the individual bits temporarily.

17. The system of claim 13, wherein the value N corresponds to the number of scan chain inputs.

18. The system of claim 14, wherein the value N corresponds to the number of scan chain outputs.

19. The system of claim 12, further comprising:
a second digital-to-analog converter configured to convert the digital output signal from the scan chains into an analog output signal;
a second analog-to-digital converter configured to receive the analog output signal and derive output bits associated with the digital output signal; and
a signal assembler configured to construct the output bits from the second analog-to-digital converter into a bit string and send to the test module in a parallel to serial fashion.

20. The system of claim 19, wherein the signal assembler further comprises a second delay buffer configured to temporarily store the bit string.
